(19) United States
(12) Patent Application Publication
(10) Pub. No.: US 2026/0106114 A1
(43) Pub. Date: Apr. 16, 2026

(54) PLASMA CONTROL APPARATUS

(71) Applicant: Samsung Electronics Co., Ltd., Suwon-si (KR)

(72) Inventors: Sanghoon Jung, Suwon-si (KR); Hadong Jin, Suwon-si (KR); Taekjin Kim, Suwon-si (KR); Hakyoung Kim, Suwon-si (KR); Haewook Park, Suwon-si (KR); Dougyong Sung, Suwon-si (KR); Junho Im, Suwon-si (KR); Minnhoo Choi, Suwon-si (KR)

(73) Assignee: Samsung Electronics Co., Ltd., Suwon-si (KR)

(21) Appl. No.: 19/218,014

(22) Filed: May 23, 2025

(30) Foreign Application Priority Data
Oct. 10, 2024 (KR) 10-2024-0138025

(51) Int. Cl. H01J 37/32

(52) U.S. Cl. CPC H01J 37/32183; H01J 37/32146

(57) ABSTRACT

A plasma control apparatus includes a first RF circuit, and a second RF circuit connected to an upper electrode and a lower electrode of a plasma chamber, respectively. The apparatus includes a plurality of RF generators, a plurality of voltage sensors associated with the RF circuits, and a controller configured to determine a waveforms of RF voltage signal components at the electrodes of the plasma chamber; and adjust a first phase of the first RF source power signal such that a first error between the first waveform of the first RF voltage signal component and a first target waveform of the first RF voltage signal component is minimized; and adjust a second phase of the second RF source power signal such that a second error between the second waveform of the second RF voltage signal component and a second target waveform of the second RF voltage signal component is minimized.

### CROSS-REFERENCE TO RELATED APPLICATION

This application claims priority from Korean Patent Application No. 10-2024-0138025, filed on Oct. 10, 2024, in the Korean Intellectual Property Office, and all the benefits accruing therefrom under 35 U.S.C. § 119, the entire contents of which are hereby incorporated by reference.

### TECHNICAL FIELD

Apparatuses and methods consistent with some embodiments of the present disclosure relate to a plasma control apparatus, and more particularly, to a plasma control apparatus that generates plasma by supplying a radio frequency (RF) power to a plasma chamber.

### BACKGROUND

A capacitively-coupled plasma (CCP) chamber is a chamber which generates plasma by applying an RF power to a capacitor-shaped electrode. When a high-frequency RF power is applied to an upper or a lower electrode of the CCP chamber, a phenomenon in which harmonic components are generated due to the nonlinearity of plasma may occur.

Due to the generation of the harmonic components, density distribution of plasma formed inside the CCP chamber may be non-uniform, resulting in undesirable process variations.

### SUMMARY

Some embodiments consistent with the present disclosure provide a plasma control apparatus that generates uniformly distributed plasma inside a chamber.

The objectives to be solved by some embodiments of the present disclosure are not limited to the objectives mentioned above, and other objectives may be clearly understood by one of ordinary skill in the art from the following description.

Some embodiments consistent with the present disclosure provide a plasma control apparatus comprising a first radio frequency (RF) circuit connected to an upper electrode of a plasma chamber, a first RF generator associated with the first RF circuit, the first RF generator configured to supply a first RF source power signal to the upper electrode. The apparatus includes a second RF circuit connected to a lower electrode of the plasma chamber, a second RF generator associated with the second RF circuit, the second RF generator configured to supply a second RF source power signal to the lower electrode, a first voltage sensor configured to obtain a first voltage signal information associated with the first RF circuit, a second voltage sensor configured to obtain a second voltage signal information associated with the second RF circuit, and a controller communicatively coupled with the first and the second RF circuits. The controller is configured to determine a first waveform of a first RF voltage signal component at the upper electrode based on the first voltage signal information, determine a second waveform of a second RF voltage signal component at the lower electrode based on the second voltage signal information, adjust a first phase of the first RF source power signal such that a first error between the first waveform of the first RF voltage signal component and a first target waveform of the first RF voltage signal component is minimized, and adjust a second phase of the second RF source power signal such that a second error between the second waveform of the second RF voltage signal component and a second target waveform of the second RF voltage signal component is minimized.

Some embodiments consistent with the present disclosure provide a plasma control apparatus including a housing connected to a ground potential, the housing comprising a plasma formation space, an upper electrode arranged in an upper portion of the plasma formation space, a lower electrode arranged in a lower portion of the plasma formation space, the lower electrode comprising an upper surface configured to receive a substrate, a first RF circuit connected to the upper electrode. The first RF circuit comprises a first radio frequency (RF) generator configured to supply a first RF source power signal to the first electrode, a first matching circuit connected to the first RF generator and configured to adjust an impedance of the first RF source power signal, and a first voltage sensor connected to the first matching circuit and the upper electrode and configured to obtain a first voltage signal information, a second RF circuit connected to the lower electrode. The second RF circuit comprises a second radio frequency (RF) generator configured to supply a second RF source power signal to the lower electrode, a second matching circuit connected to the second RF generator and configured to adjust an impedance of the second RF source power signal, and a second voltage sensor connected to the second matching circuit and the lower electrode and configured to obtain a second voltage signal information, wherein the upper electrode and the lower electrode are configured to generate a plasma for treating the substrate. The apparatus includes a controller communicatively coupled with the first and the second RF circuits. The controller is configured to determine a first waveform of a first RF voltage signal component at the upper electrode based on the first voltage signal information, determine a second waveform of a second RF voltage signal component at the lower electrode based on the second voltage signal information, adjust a first phase of the first RF source power signal such that a first error between the first waveform of the first RF voltage signal component and a first target waveform of the first RF voltage signal component is minimized, and adjust a second phase of the second RF source power signal such that a second error between the second waveform of the second RF voltage signal component and a second target waveform of the second RF voltage signal component is minimized.

Some embodiments consistent with the present disclosure provide a plasma control apparatus including an upper electrode arranged in an upper portion of a plasma formation space, a lower electrode arranged in a lower portion of the plasma formation space, a first radio frequency (RF) generator configured to supply a first RF source power signal to the upper electrode, a first voltage sensor connected to the upper electrode and configured to obtain a first voltage signal information, a second radio frequency (RF) generator configured to supply a second RF source power signal to the lower electrode, a second voltage sensor connected to the lower electrode and configured to obtain a second voltage signal information, and a controller communicatively coupled with the first and the second RF generators. The controller is configured to determine a first waveform of a first RF voltage signal component at the upper electrode based on the first voltage signal information, determine a second waveform of a second RF voltage signal component at the lower electrode based on the second voltage signal information, adjust a first phase of the first RF source power signal such that a first error between the first waveform of the first RF voltage signal component and a first target waveform of the first RF voltage signal component is minimized, and adjust a second phase of the second RF source power signal such that a second error between the second waveform of the second RF voltage signal component and a second target waveform of the second RF voltage signal component is minimized.

### BRIEF DESCRIPTION OF THE DRAWINGS

The accompanying drawings are included to provide a further understanding of disclosed example embodiments, and are incorporated in and constitute a part of this specification. In the drawings:

FIG. 1 is a configuration view schematically illustrating a plasma control apparatus, consistent with some embodiments of the present disclosure.

FIG. 2 is a flowchart illustrating a controlling method of a plasma control apparatus, consistent with some embodiments of the present disclosure.

FIG. 3 is a flowchart illustrating a controlling method of a plasma control apparatus, consistent with some embodiments of the present disclosure.

FIG. 4 is a cross-sectional view illustrating an upper radio frequency (RF) path and a lower RF path in the plasma control apparatus, consistent with some embodiments of the present disclosure.

FIG. 5 is a conceptual view illustrating a controlling method of an upper/lower RF generator by using a controller, consistent with some embodiments of the present disclosure.

FIG. 6 is a flowchart illustrating a controlling method of a plasma control apparatus, consistent with some embodiments of the present disclosure.

FIGS. 7A and 7B illustrate a cross-sectional view and a graph illustrating a controlling method of a plasma control apparatus, respectively, consistent with some embodiments of the present disclosure.

FIG. 8 is a graph illustrating a controlling method of a plasma control apparatus, consistent with some embodiments of the present disclosure.

FIG. 9 is a configuration view schematically illustrating a plasma control apparatus, consistent with some embodiments of the present disclosure.

FIG. 10 is a configuration view schematically illustrating a plasma control apparatus, consistent with some embodiments of the present disclosure.

### DETAILED DESCRIPTION

Exemplary embodiments of the present disclosure will now be described more fully with reference to the accompanying drawings, in which example embodiments are shown. The same reference numerals are used for the same components in the drawings, and redundant descriptions thereof are omitted.

As used herein, a horizontal direction may include a first horizontal direction (X direction) and a second horizontal direction (Y direction) that intersect each other. A direction intersecting the first horizontal direction (X direction) and the second horizontal direction (Y direction) may be referred to as a vertical direction (Z direction). As used herein, a vertical level may be referred to as a height level according to a vertical direction (Z direction) of an arbitrary configuration.

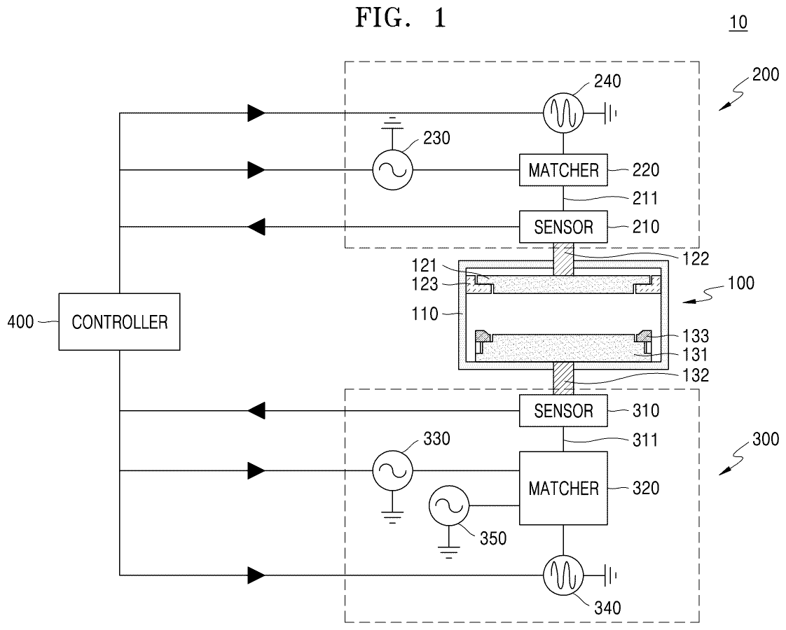

FIG. 1 is a configuration view schematically illustrating a plasma control apparatus, consistent with some embodiments of the present disclosure.

Referring to FIG. 1, a plasma control apparatus 10 may include a plasma chamber 100, an upper radio frequency (RF) circuit 200, a lower RF circuit 300, and a controller 400.

The plasma chamber 100 may include a housing 110, an upper electrode 121, an upper metal rod 122, an upper mount 123, a lower electrode 131, a lower metal rod 132, and an edge ring 133.

The housing 110 may define a plasma formation space and seal the plasma formation space from the outside. In some embodiments, the housing 110 may be formed of a metal material and may be connected to a ground potential, thereby blocking noise from the outside during a plasma process. An insulating liner may be arranged inside the housing 110, and the insulating liner may protect the housing 110 and cover metal structures that protrude from the housing 110, thereby preventing the occurrence of arcing. The insulating liner may be made of a material including, but not limited to, a ceramic, quartz, or the like.

The housing 110 may have, for example, a circular tubular shape. However, the shape of the housing 110 is not limited to the circular tubular shape, and the housing 110 may also have other shapes. For example, the housing 110 may have a top surface with an upwardly-convex dome shape, while the side surface of the housing 110 may have a circular tubular shape. In some embodiments, the housing 110 may have a rectangular solid shape.

The housing 110 may include sidewalls, an upper surface, and a lower surface of the plasma chamber 100, and may also be referred to as a “plasma chamber housing,” a “chamber housing,” or a “chamber body.”

The upper electrode 121 may be arranged inside the housing 110 and may be arranged in an upper portion of the plasma formation space. The upper electrode 121 may receive an upper RF source power from the upper RF circuit 200.

The upper electrode 121 may have a shape similar to that of two circular plates having the same central axis and different sizes, as shown in FIG. 1. However, the shape of the upper electrode 121 is not limited to the above-described shape, and the upper electrode 121 may have various shapes. For example, a plurality of recesses may be formed in the lower surface of the upper electrode 121. In some embodiments, the lower surface of the upper electrode 121 may also have a rectangular shape.

The upper electrode 121 may also perform a function of spraying gas into the plasma formation space. That is, the upper electrode 121 may include a plurality of gas spray holes, and may spray gas into the plasma formation space through the plurality of gas spray holes by receiving gas from a gas supply source arranged outside the housing 110. Here, the gas supplied from the external gas supply source may mean all gases required for a plasma process such as a source gas, a reaction gas, a purge gas, an etching gas, and the like.

The upper electrode 121 may be interchangeably referred to as a shower head, an upper plate, or an upper discharge plate. In the present disclosure, however, for the convenience of explanation, the upper electrode 121 is collectively referred to herein as the “upper electrode 121”.

The upper metal rod 122 may be connected to the upper surface of the upper electrode 121 and connected to the upper RF circuit 200. The upper metal rod 122 may supply the RF power to the upper electrode 121. The upper metal rod 122 may support and fix the upper electrode 121 at an upper part of the upper electrode 121. In some embodiments, the upper metal rod 122 may perform a function of discharging heat transferred from the upper electrode 121 to the outside. The upper metal rod 122 may be a cylindrical metal rod. However, the shape of the upper metal rod 122 is not limited to the cylindrical shape, and the upper metal rod 122 may be implemented with various shapes, as appropriate.

The upper mount 123 may be configured to be coupled to upper sidewalls of the housing 110. In some embodiments, the upper mount 123 may perform a function of supporting the upper electrode 121 so that the upper electrode 121 may be fixed to the upper portion of the plasma formation space. The upper mount 123 may allow the upper electrode 121 and the housing 110 to be insulated from each other. The upper mount 123 may be made from an electrical insulator material such as a ceramic, a polymer, or the like.

The lower electrode 131 may be arranged inside the housing 110 and arranged in a lower portion of the plasma formation space. The lower electrode 131 may receive a lower RF source power and a bias potential from the lower RF circuit 300.

An object to be treated in a plasma process, i.e., a wafer (e.g., a substrate), may be arranged on the upper surface of the lower electrode 131. The lower electrode 131 may fix the substrate based on an electrostatic force. In some embodiments, the upper surface of lower electrode 131 may be configured to receive the substrate (e.g., a wafer). In some embodiments, the upper surface of lower electrode 131 may be configured to receive and/or secure the substrate (e.g., a wafer).

The lower electrode 131 may be referred to as an electrostatic chuck (ESC), a lower plate, or a lower discharge plate. In this present disclosure, however, for the convenience of explanation, the lower electrode 131 is collectively referred to herein as the “lower electrode 131.”

As previously described, the upper RF source power may be applied to the upper electrode 121, the lower RF source power may be applied to the lower electrode 131, and the housing 110 may be connected to the ground potential. Thus, the plasma chamber 100 may be implemented as a triode chamber.

The lower metal rod 132 may be connected to the lower surface of the lower electrode 131 and connected to the lower RF circuit 300. The lower metal rod 132 may supply the RF power to the lower electrode 131. The lower metal rod 132 may support and fix the lower electrode 131 at a lower part of the lower electrode 131. In addition, the lower metal rod 132 may also perform a function of discharging heat transferred from the lower electrode 131 to the outside. The lower metal rod 132 may be a cylindrical metal rod. However, the shape of the lower metal rod 132 is not limited to the cylindrical shape, and the lower metal rod 132 may be implemented in various shapes, as appropriate.

The edge ring 133 may be arranged at the edge of the lower electrode 131 and may surround the wafer arranged on the upper surface of the lower electrode 131. The edge ring 133 may perform a function of protecting an outer circumferential surface of the wafer from plasma and preventing the plasma from being concentrated only on an edge area of the wafer. In addition, the edge ring 133 may be arranged to be spaced apart laterally from the upper surface of the lower electrode 131 at a certain distance.

The upper RF circuit 200 may include an upper voltage/current (V/I) sensor 210, an upper cable 211, an upper matcher 220, an upper RF generator 230, and an upper harmonic generator 240.

The upper V/I sensor 210 may be coupled to an upper RF transmission line for connecting the upper matcher 220 to the upper electrode 121. Here, the upper RF transmission line may extend from an output terminal of the upper matcher 220 to an upper surface of the upper electrode 121, and may perform a function of transmitting the RF power to the upper electrode 121. In an example, the upper RF transmission line may include the upper cable 211 and the upper metal rod 122. Here, the upper cable 211 may be implemented as a coaxial cable, an RF strap, or the like.

The upper V/I sensor 210 may include voltage pickup and current pickup, and the voltage pickup and the current pickup may measure the voltage and current of the RF power transmitted through the upper RF transmission line.

In some embodiments, the upper V/I sensor 210 may include a cylindrical body and a cylindrical through hole formed inside the body. The upper RF transmission line may be arranged inside the through hole of the upper V/I sensor 210, and may penetrate from the upper surface of the cylindrical body to the lower surface of the body along the through hole. The upper V/I sensor 210 may include voltage pickup and current pickup arranged along a boundary of the through hole. Each of the voltage pickup and the current pickup may measure the voltage and current of the RF power transmitted through the upper RF transmission line arranged inside the through hole.

The configuration of the upper V/I sensor 210 described above is exemplary, and the upper V/I sensor 210 may sense a voltage and a current of the upper RF power transmitted through the upper RF transmission line based on various configurations.

The upper V/I sensor 210 may obtain information about an upper RF voltage. Here, the “upper RF voltage” refers to a voltage in which an upper fundamental voltage applied to the upper electrode 121 and a plurality of upper harmonic voltages are synthesized. Here, the “upper fundamental voltage” refers to a fundamental voltage component applied to the upper electrode 121 due to the upper RF source power supplied to the upper electrode 121 by the upper RF generator 230, and the “plurality of upper harmonic voltages” refers to a plurality of harmonic voltage components applied to the upper electrode 121 due to the nonlinearity of the plasma. The frequency of each of the plurality of upper harmonic voltages may be an integer multiple of the frequency of the upper fundamental voltage. For example, the frequency of a first upper harmonic voltage may be twice the frequency of the upper fundamental voltage, and the frequency of a second upper harmonic voltage may be three times the frequency of the upper fundamental voltage.

The “information about the upper RF voltage” refers to voltage information sensed by the upper V/I sensor 210 at one point of the upper RF transmission line. Additionally, the information about the upper RF voltage may include a waveform of the upper fundamental voltage sensed by the upper V/I sensor 210 at one point of the upper RF transmission line and waveforms of a plurality of upper harmonic voltages.

In some embodiments, the upper V/I sensor 210 may be arranged between the upper matcher 220 and the upper electrode 121. As shown in FIG. 1, the upper V/I sensor 210 may be arranged between the upper matcher 220 and the upper surface of the housing 110.

In some embodiments, a distance between the upper V/I sensor 210 and the upper matcher 220 may be greater than a distance between the upper V/I sensor 210 and the upper surface of the housing 110. The “information about the upper RF voltage” obtained by the upper V/I sensor 210 may be used to estimate the upper RF voltage applied to the upper electrode 121. Thus, the upper V/I sensor 210 may be arranged adjacent to the upper electrode 121 to minimize the distortion of signals. For example, the upper V/I sensor 210 may be arranged closer to the upper surface of the housing 110 than the upper matcher 220. For example, the upper V/I sensor 210 may be arranged on the upper surface of the housing 110 or in a position very close to the upper surface of the housing 110.

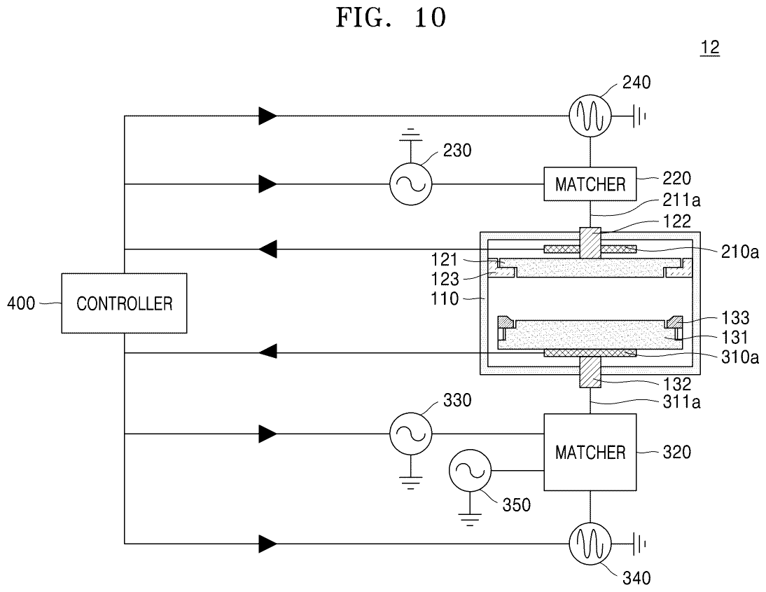

In the above description, it is assumed that the upper V/I sensor 210 is arranged outside the housing 110. However, the upper V/I sensor 210 may be arranged at one point of the upper RF transmission line present inside the housing 110. The upper V/I sensor 210 arranged inside the housing 110 will be described with reference to FIG. 10.

The upper matcher 220 may adjust the impedance so that the upper RF source power may be maximally transmitted from the upper RF generator 230 to the upper electrode 121. The upper matcher 220 may adjust the impedance so that the upper RF source power may be maximally transmitted to the upper electrode 121. For example, the upper matcher 220 may adjust the impedance to 50 ohms (22) so that the efficiency of the upper RF source power transmitted from the upper RF generator 230 to the upper electrode 121 may be optimized. In some embodiments, upper matcher 220 may comprise a matching circuit, also referred to as an impedance matching circuit.

The upper RF generator 230 may supply the upper RF source power to the upper electrode 121. The upper RF generator 230 may generate an RF power having a frequency in the range of several MHz to several tens of MHz. In addition, the upper RF generator 230 may generate and output the RF power of several hundreds to several tens of thousands of watts (W). For example, the upper RF generator 230 may output the upper RF source power of 1,000 W having the frequency of 60 MHz.

In some embodiments, the upper RF generator 230 may change the phase of the upper RF source power. The upper RF generator 230 may receive a control signal indicating to change the phase by “+30 degrees” and may change the phase of the upper RF source power output from the upper RF generator 230 by “+30 degrees.”

The upper harmonic generator 240 may be configured to generate and output a plurality of upper harmonic powers having a frequency that is an integer multiple of the upper RF source power, and may supply the plurality of upper harmonic powers to the upper electrode 121. In some embodiments, the upper harmonic generator 240 may output the plurality of upper harmonic powers, so that the upper RF source power and a harmonic voltage having the same frequency as that of the plurality of upper harmonic voltages applied to the upper electrode 121 due to the nonlinearity of the plasma, may be applied to the upper electrode 121.

As an example, when the frequency of the upper RF source power is 60 MHz, the upper harmonic generator 240 may output a first upper harmonic power having the frequency of 120 MHz and a second upper harmonic power having the frequency of 180 MHz, respectively. Thus, a first upper harmonic voltage and a second upper harmonic voltage each having the frequency of 120 MHz and 180 MHz, respectively, may be applied to the upper electrode 121.

The lower RF circuit 300 may include a lower V/I sensor 310, a lower cable 311, a lower matcher 320, a lower RF generator 330, a lower harmonic generator 340, and a lower bias RF generator 350.

The lower V/I sensor 310 may be coupled to a lower RF transmission line for connecting the lower matcher 320 to the lower electrode 131. Here, the lower RF transmission line may be a line that extends from an output terminal of the lower matcher 320 to a lower surface of the lower electrode 131, and may perform a function of transmitting the RF power to the lower electrode 131. In an example, the lower RF transmission line may include the lower cable 311 and the lower metal rod 132. Here, the lower cable 311 may be implemented as a coaxial cable, an RF strap, or the like.

The lower V/I sensor 310 may include voltage pickup and current pickup, and the voltage pickup and the current pickup may measure the voltage and current of the RF power transmitted through the lower RF transmission line. A description of a method of obtaining voltage and current information at one point of the lower RF transmission line by using the lower V/I sensor 310 is redundant with the description of the upper V/I sensor 210 described above and thus, a detailed description thereof will be omitted.

The lower V/I sensor 310 may obtain information about a lower RF voltage. Here, the “lower RF voltage” refers to a voltage in which a lower fundamental voltage applied to the lower electrode 131 and a plurality of lower harmonic voltages are synthesized. Here, the “lower fundamental voltage” refers to a fundamental voltage component applied to the lower electrode 131 due to the lower RF source power supplied to the lower electrode 131 by the lower RF generator 330, and “the plurality of lower harmonic voltages” refers to a plurality of harmonic voltage components applied to the lower electrode 131 due to the nonlinearity of the plasma. The frequency of each of the plurality of lower harmonic voltages may be an integer multiple of the frequency of the lower fundamental voltage. For example, the frequency of a first lower harmonic voltage may be twice the frequency of the lower fundamental voltage, and the frequency of a second lower harmonic voltage may be three times the frequency of the lower fundamental voltage.

The “information about the lower RF voltage” refers to voltage information sensed by the lower V/I sensor 310 at one point of the lower RF transmission line. Additionally, the information about the lower RF voltage may include a waveform of the lower fundamental voltage sensed by the lower V/I sensor 310 at any one point of the lower RF transmission line and waveforms of a plurality of lower harmonic voltages.

The lower V/I sensor 310 may be arranged between the lower matcher 320 and the lower electrode 131. As shown in FIG. 1, the lower V/I sensor 310 may be arranged between the lower matcher 320 and the lower surface of the housing 110.

In some embodiments, a distance between the lower V/I sensor 310 and the lower matcher 320 may be greater than a distance between the lower V/I sensor 310 and the lower surface of the housing 110. As previously described with reference to the upper V/I sensor 210, the upper V/I sensor 210 may be arranged adjacent to the upper electrode 121, and the lower V/I sensor 310 may be arranged adjacent to the lower electrode 131. The lower V/I sensor 310 may be arranged closer to the lower surface of the housing 110 than the lower matcher 320. For example, the lower V/I sensor 310 may be arranged on the lower surface of the housing 110 or in a position very close to the lower surface of the housing 110.

In the above description, it is assumed only that the lower V/I sensor 310 is arranged outside the housing 110. However, the lower V/I sensor 310 may be arranged at one point of the lower RF transmission line present inside the housing 110. The lower V/I sensor 310 arranged inside the housing 110 will be described with reference to FIG. 10.

In some embodiments, the lower matcher 320 may adjust the impedance so that the lower RF source power may be maximally transmitted from the lower RF generator 330 to the lower electrode 131. In some embodiments, lower matcher 320 may comprise a matching circuit, also referred to as an impedance matching circuit.

The lower RF generator 330 may supply the lower RF source power to the lower electrode 131. The frequency of the lower RF source power may be identical or substantially similar to the frequency of the upper RF source power. In the context of this disclosure, two or more power signals may be deemed to have “substantially similar frequency” if the difference in frequency of the waveforms representing the power signals is ≤2%. For example, when the frequency of the upper RF source power is 60 MHz, the frequency of the lower RF source power may be in the range of 58.8 MHz-61.2 MHz. In addition, the lower RF generator 330 may change the phase of the lower RF source power.

The lower harmonic generator 340 may generate and output a plurality of lower harmonic powers having a frequency that is an integer multiple of the lower RF source power, and may supply the plurality of lower harmonic powers to the lower electrode 131. The lower harmonic generator 340 may output the plurality of lower harmonic powers, so that the lower RF source power and the harmonic voltage having the same frequency as that of the plurality of lower harmonic voltages applied to the lower electrode 131 due to the nonlinearity of the plasma, may be applied to the lower electrode 131.

The lower bias RF generator 350 may be connected to the lower matcher 320 and may supply a bias voltage to the wafer arranged on the upper surface of the lower electrode 131. The bias voltage supplied to the wafer may attract ions present in the plasma formation space to the surface of the wafer.

The controller 400 may be operatively connected to the upper RF circuit 200 and the lower RF circuit 300 to control the overall operation of the plasma control apparatus 10. The controller 400 may control, in particular, elements of the upper RF circuit 200 and the lower RF circuit 300. The controller 400 may obtain information about the upper RF voltage and information about the lower RF voltage from the upper V/I sensor 210 and the lower V/I sensor 310, respectively, and control the upper RF generator 230, the upper harmonic generator 240, the lower RF generator 330, and/or the lower harmonic generator 340.

The controller 400 may include at least one of a microprocessor, a digital signal processor, or a processing apparatus similar thereto. In addition, although FIG. 1 illustrates only one controller 400, this is only for convenience of explanation, and the controller 400 may include an upper controller connected to the upper RF circuit 200 and a lower controller connected to the lower RF circuit 300, and may be implemented as two or more devices.

Although FIG. 1 illustrates that the plasma control apparatus 10 includes the plasma chamber 100, in some embodiments, the plasma control apparatus 10 may not include the plasma chamber 100. For example, the plasma control apparatus 10 may include only the upper RF circuit 200, the lower RF circuit 300, and the controller 400.

In some embodiments, the plasma control apparatus 10 may include the configurations described above, thereby enabling the density of plasma formed inside the plasma chamber 100 to be uniformly distributed over the entire area of the plasma formation space. The plasma control apparatus 10 may change the phase of each of the upper RF source power and the lower RF source power, thereby suppressing a standing wave effect that may occur due to the plurality of upper harmonic voltage components and the plurality of lower harmonic voltage components. Here, the standing wave effect refers to an effect in which the density of plasma distributed only in some specific areas among the plasma formation regions becomes abnormally high.

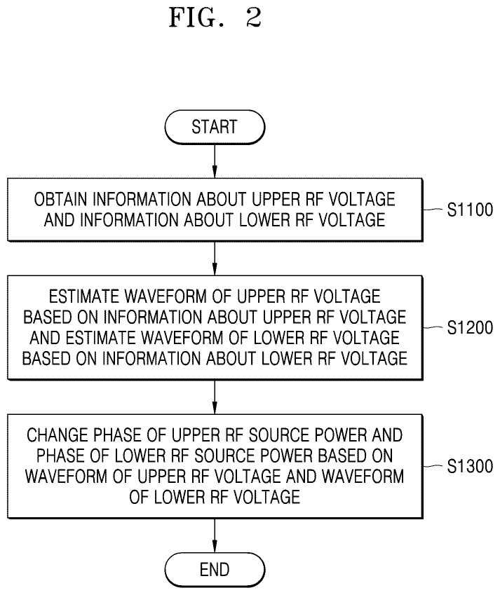

FIGS. 2-6 illustrate example methods of suppressing the standing wave effect by changing phases of the upper RF source power and the lower RF source power by using the plasma control apparatus 10, consistent with some embodiments of the present disclosure.

FIG. 2 is a flowchart illustrating a controlling method of the plasma control apparatus 10, consistent with some embodiments of the present disclosure. This will be described with reference to FIG. 1 together.

Referring to FIG. 2, in the controlling method of the plasma control apparatus 10, in operation S1100 (also referred to as ‘first operation’), obtaining information about the upper RF voltage and information about the lower RF voltage may be performed.

In some embodiments, in the first operation (S1100), the upper V/I sensor 210 may obtain information about the upper RF voltage at one point of the upper RF transmission line. In addition, the lower V/I sensor 310 may obtain information about the upper RF voltage at one point of the lower RF transmission line.

In some embodiments, in the first operation (S1100), each of the upper V/I sensor 210 and the lower V/I sensor 310 may provide the information about the upper RF voltage and the information about the lower RF voltage to the controller 400.

In operation S1200 (also referred to as ‘second operation’), an operation of estimating a waveform of the upper RF voltage based on the information about the upper RF voltage and estimating a waveform of the lower RF voltage based on information about the lower RF voltage may be performed.

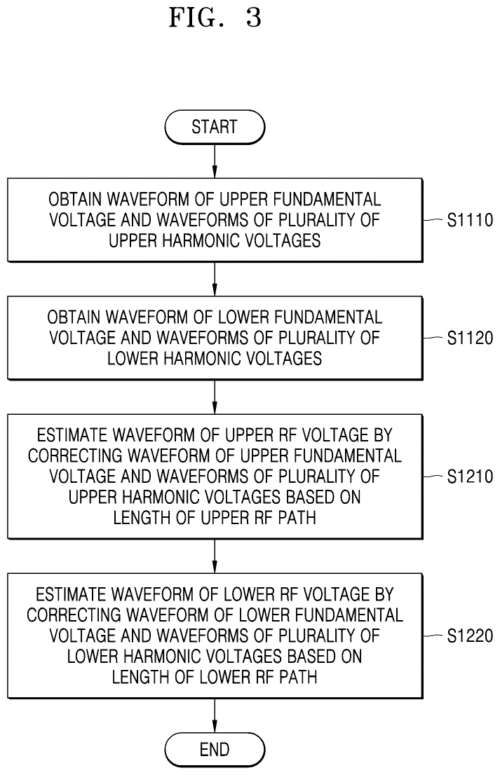

Here, the information about the upper/lower RF voltage refers to voltage information measured by the upper/lower V/I sensor at one point of the upper/lower RF transmission line. That is, the upper RF voltage and the lower RF voltage directly applied to the upper electrode 121 and the lower electrode 131, respectively, may not be directly measured. Thus, the controller 400 needs to estimate the upper RF voltage and the lower RF voltage based on the information about the upper/lower RF voltage. A description of a method of estimating the waveforms of the upper RF voltage and the lower RF voltage by using the controller 400 will be described with reference to FIG. 3.

In operation S1300 (also referred to as ‘third operation’), an operation of changing the phase of the upper RF source power and the phase of the lower RF source power based on the waveform of the upper RF voltage and the waveform of the lower RF voltage may be performed.

As the upper/lower RF source power is supplied to the upper electrode 121 and the lower electrode 131, an upper/lower fundamental voltage may be applied to the upper electrode 121 and the lower electrode 131. In addition, as the upper/lower fundamental voltage is applied to the upper electrode 121 and the lower electrode 131, the plurality of upper/lower harmonic voltages may be additionally applied to the upper electrode 121 and the lower electrode 131, respectively. That is, the plurality of upper/lower harmonic voltages may be components that occur dependently on the upper/lower fundamental voltage.

Thus, when the phase of the upper/lower RF source power is changed, the phase of the upper/lower fundamental voltage may be changed, and the phases of the plurality of upper/lower harmonic voltages may also be changed based on the dependency as previously described.

In some embodiments, in the third operation (S1300), the controller 400 may control the upper RF generator 230 to change the phase of the upper RF source power based on the waveform of the upper RF voltage and the waveform of the lower RF voltage, and may control the lower RF generator 330 to change the phase of the lower RF source power. The controller 400 may control each of the upper RF generator 230 and the lower RF generator 330 to change the phase of the upper/lower RF source power, or to change the waveform of the upper/lower RF voltage to be identical or substantially similar to the waveform of the target upper/lower voltage. Here, in this context, two or more waveforms may be deemed to “substantially similar” if the difference in amplitudes of the waveforms is ≤2%, if the difference in phases of the waveforms is ≤2%, if the difference in wavelengths of the waveforms≤2%, and if the difference in frequencies of the waveforms is ≤2%. In other words, two or more waveforms may be deemed to be “substantially similar” if, when superimposed, the difference between the amplitudes, wavelengths, frequencies, and phases of the waveforms is less than a predetermined threshold.

Here, the “waveform of the target upper/lower voltage” refers to the waveform of the voltage applied to the upper/lower electrode for uniform distribution of plasma inside the plasma chamber 100, and the “waveform of the target upper/lower voltage” may refer to a set waveform. Each “waveform of the target upper/lower voltage” may be determined based on the structural features and the material characteristics of the plasma chamber 100, the frequency of the upper/lower RF source power, and the type of gas supplied inside the plasma chamber 100. Here, geometrical characteristics of the plasma chamber 100 may include, but are not limited to, the size of the housing 110, the size of the upper electrode 121, the size of the lower electrode 131, a distance between the upper electrode 121 and the sidewall of the housing 110, a distance between the lower electrode 131 and the sidewall of the housing 110, and the material characteristics of the plasma chamber 100 may include, but are not limited to, the physical characteristics and chemical characteristics of each of the material constituting the housing 110, the material constituting the upper electrode 121, and the material constituting the lower electrode 131.

In some embodiments, when an RF power having the frequency of 60 MHz is applied to the upper electrode 121 and the lower electrode 131, a phenomenon in which the plasma density in the center region of the plasma chamber 100 is greatly increased due to the skin effect, i.e., a center-hot phenomenon, may occur. On the other hand, when RF powers having different frequencies are applied to the upper electrode 121 and the lower electrode 131, a phenomenon in which the plasma density of an edge region of the plasma chamber 100 is greatly increased due to the skin effect, i.e., an edge-hot phenomenon, may occur.

In some embodiments, even in a situation where the frequency of the RF power applied to the upper/lower electrode is constant, a center-hot phenomenon or an edge-hot phenomenon may occur depending on whether the type of gas supplied into the plasma chamber 100 is changed. This also applies when the structural features or material characteristics of the plasma chamber 100 are changed. For example, even in a situation where the frequency of the RF power applied to the upper/lower electrode and the type of gas supplied into the plasma chamber 100 are constant, a center-hot phenomenon or an edge-hot phenomenon may occur as the distance between the upper electrode 121 and the lower electrode 131 becomes longer or shorter.

Thus, the plasma control apparatus 10 may predetermine a plurality of waveforms of the target upper/lower voltage according to various operating conditions of the plasma chamber 100, select the waveforms of the target upper/lower voltage corresponding to the current operating condition, and control the waveforms of the upper/lower RF voltage to be changed to be identical or substantially similar to the selected waveform of the target upper/lower voltage. As previously described, two or more waveforms may be deemed to be substantially similar if the difference in amplitudes of the waveforms is ≤2%, if the difference in phases of the waveforms is ≤2%, if the difference in the wavelengths of the waveforms is ≤2%, and if the difference in frequencies of the waveforms is ≤2%. In some embodiments, the plurality of waveforms of target upper/lower voltage according to various operating conditions may be defined by a user through past operating experience of the plasma chamber 100, for example.

As an example, under operating conditions where upper and lower RF source power having a frequency of 60 MHz is supplied to upper and lower electrodes of the plasma chamber 100 to which chlorine (Cl₂) gas is supplied, an edge-hot phenomenon may frequently occur. In this case, the plasma control apparatus 10 may identify each of the waveform of the upper RF voltage and the waveform of the lower RF voltage that may suppress the edge-hot phenomenon, and determine the identified waveform of the upper RF voltage as the waveform of the target upper voltage and determine the waveform of the identified lower RF voltage as the waveform of the target lower voltage.

In some embodiments, the plasma control apparatus 10 may change the waveforms of the upper and lower RF voltages applied to the upper and lower electrodes to be identical or substantially similar to the waveforms of the target upper and lower voltages by changing the phases of the upper and lower RF source powers, respectively, thereby making the distribution of the plasma density uniform. Two or more voltage signal waveforms (e.g., upper and lower RF voltage signal waveforms applied to the upper and lower electrode, respectively) may be deemed to be substantially similar if the difference in amplitudes of the waveforms is ≤2%, if the difference in phases of the waveforms is ≤2%, if the difference in wavelengths of the waveforms is ≤2%, and if the difference in frequencies of the waveforms is ≤2%. In the following description of FIG. 3, a method of estimating the upper/lower RF voltage applied to the upper/lower electrode by using the plasma control apparatus 10 is discussed.

FIG. 3 illustrates a flowchart illustrating a controlling method of the plasma control apparatus 10, consistent with some embodiments of the present disclosure. This will be described with reference to FIG. 1 together.

Referring to FIG. 3, in the first operation (S1110), the controlling method of the plasma control apparatus 10 may include obtaining a waveform of the upper fundamental voltage and waveforms of the plurality of upper harmonic voltages and in the second operation (S1120) obtaining a waveform of the lower fundamental voltage and waveforms of the plurality of lower harmonic voltages.

Although FIG. 3 illustrates that the operation of obtaining the waveform of the upper fundamental voltage and the waveforms of the plurality of upper harmonic voltages (S1110) is performed and the operation of obtaining the waveform of the lower fundamental voltage and the waveforms of the plurality of lower harmonic voltages (S1120) is performed, the operation of obtaining the waveform of the upper fundamental voltage and the waveforms of the plurality of upper harmonic voltages (S1110) and the operation of obtaining the waveform of the lower fundamental voltage and the waveforms of the plurality of lower harmonic voltages (S1120) may be simultaneously performed. In some embodiments, the operation of obtaining the waveform of the lower fundamental voltage and the waveforms of the plurality of lower harmonic voltages (S1120) may be performed before the operation of obtaining the waveform of the upper fundamental voltage and the waveforms of the plurality of upper harmonic voltages (S1110).

In some embodiments, the upper V/I sensor 210 may obtain the waveform of the upper fundamental voltage and the waveforms of the plurality of upper harmonic voltages and supply the obtained waveform of the upper fundamental voltage and the obtained waveforms of the plurality of upper harmonic voltages to the controller 400. The lower V/I sensor 310 may obtain the waveform of the lower fundamental voltage and the waveforms of the plurality of lower harmonic voltages and supply the obtained waveform of the lower fundamental voltage and the obtained waveforms of the plurality of lower harmonic voltages to the controller 400.

In some embodiments, the plurality of upper/lower harmonic voltages may include only the first upper/lower harmonic voltage and the second upper/lower harmonic voltage. As the third through nth upper/lower harmonic voltages have a short wavelength, the third through nth upper/lower harmonic voltages may have three or more antinodes and nodes inside the plasma chamber 100. Thus, there is less possibility that third through nth upper/lower harmonic voltages may cause non-uniform distribution of plasma. On the other hand, the first upper/lower harmonic voltage and the second upper/lower harmonic voltage include only one to two antinodes and nodes, which may be more likely to cause non-uniform distribution of plasma. Thus, the upper V/I sensor 210 and the lower V/I sensor 310 may obtain only the waveform of the upper/lower fundamental voltage, the waveform of the first upper/lower harmonic voltage, and the waveform of the second upper/lower harmonic voltage and supply the obtained waveform of the upper/lower fundamental voltage, the obtained waveform of the first upper/lower harmonic voltage, and the obtained waveform of the second upper/lower harmonic voltage to the controller 400.

Subsequently, in the third operation (S1200), an operation of estimating the waveform of the upper RF voltage by correcting the waveform of the upper fundamental voltage and the waveforms of the plurality of upper harmonic voltages based on a length of an upper RF path (S1210) may be performed. In addition, an operation of estimating the waveform of the lower RF voltage by correcting the waveform of the lower fundamental voltage and the waveforms of the plurality of lower harmonic voltages based on a length of a lower RF path (S1220) may be performed.

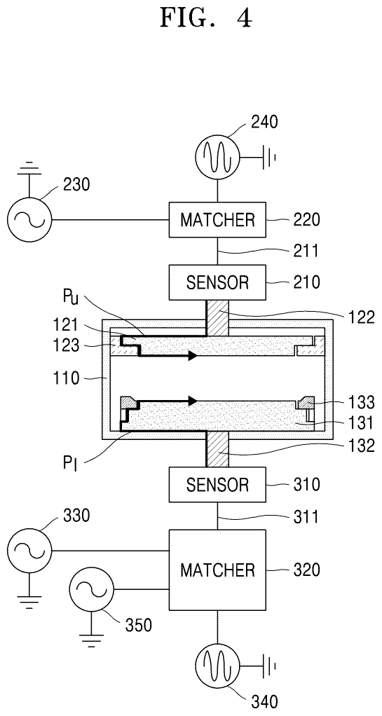

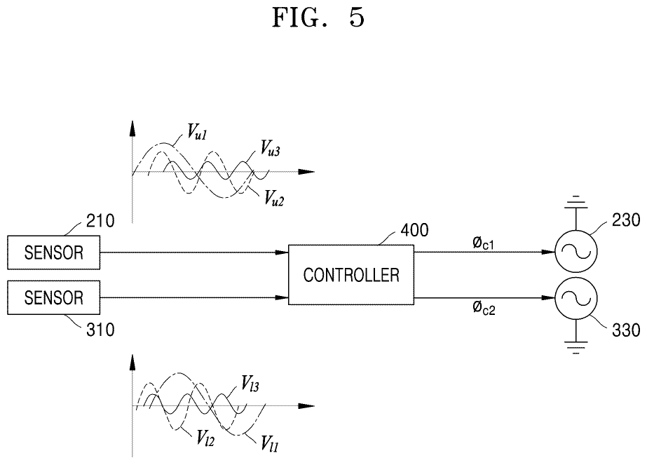

Although FIG. 3 illustrates that the operation of estimating the waveform of the upper RF voltage (S1210) is performed and the operation of estimating the waveform of the lower RF voltage (S1220) is performed, the operation of estimating the waveform of the upper RF voltage (S1210) and the operation of estimating the waveform of the lower RF voltage (S1220) may be simultaneously performed. In some embodiments, the operation of estimating the waveform of the lower RF voltage (S1220) may be performed before the operation of estimating the upper RF voltage (S1210). The operation of estimating the waveform of the upper RF voltage (S1210) and the operation of estimating the waveform of the lower RF voltage (S1220) are described with reference to FIGS. 4 and 5.

FIG. 4 is a cross-sectional view illustrating an upper RF path and a lower RF path in the plasma control apparatus, consistent with some embodiments of the present disclosure.

Referring to FIG. 4, an upper RF path Pᵤ refers to a path along which the upper RF source power is transmitted from the upper V/I sensor 210 to the lower surface of the upper electrode 121, and a lower RF path Pₗ refers to a path along which the lower RF source power is transmitted from the lower V/I sensor 310 to the upper surface of the lower electrode 131. As shown in FIG. 4, the upper RF path Pᵤ and the lower RF path Pₗ may be formed along the surface of a conductor (e.g., an electrically conducting surface). This is because the high-frequency RF power is transmitted along the surface of the conductor.

As previously described, since the upper V/I sensor 210 obtains voltage information at one point of the upper RF transmission line, a phase difference due to the length of the upper RF path Pᵤ needs to be compensated for, to estimate the waveform of the upper RF voltage applied to the lower surface of the upper electrode 121.

To compensate for the phase difference due to the length of the upper RF path Pᵤ, the controller 400 may correct each of the waveform of the upper fundamental voltage and the waveforms of the plurality of upper harmonic voltages based on the length of the upper RF path Pᵤ and synthesize the corrected waveforms to estimate the waveform of the upper RF voltage. The controller 400 may be configured to estimate the waveform of the lower RF voltage based on the same principle.

The upper RF path Pᵤ may include a path of the upper RF transmission line connected to the upper electrode 121 from the output terminal of the upper V/I sensor 210 and a shortest path through which the upper RF source power moves to one point present on the lower surface of the upper electrode 121 along the surface of the upper electrode 121.

In some embodiments, as shown in FIG. 4, when the upper V/I sensor 210 is connected to the upper surface of the upper metal rod 122, the upper RF path Pᵤ may refer to a shortest path through which the upper RF source power moves to one point present on the lower surface of the upper electrode 121 along the upper metal rod 122 and the surface of the upper electrode 121.

In some embodiments, referring to FIG. 10, when an upper V/I sensor 210a is coupled to the upper metal rod 122 inside the housing 110, the upper RF path Pᵤ may refer to a shortest path through which the upper RF source power moves to one point present on the lower surface of the upper electrode 121 along the upper metal rod 122 and the surface of the upper electrode 121 from the output terminal of the upper V/I sensor 210a.

The lower RF path Pₗ may include a path of the lower RF transmission line connected to the lower electrode 131 from the output terminal of the lower V/I sensor 310 and a shortest path through which the lower RF source power moves to one point present on the upper surface of the lower electrode 131 along the surface of the lower electrode 131.

In some embodiments, as shown in FIG. 4, when the lower V/I sensor 310 is connected to the lower surface of the lower metal rod 132, the lower RF path Pₗ may refer to a shortest path through which the lower RF source power moves to one point present on the upper surface of the lower electrode 131 along the lower metal rod 132 and the surface of the lower electrode 131.

In some embodiments, referring to FIG. 10, when a lower V/I sensor 310a is coupled to the lower metal rod 132 inside the housing 110, the lower RF path Pₗ may refer to a shortest path through which the lower RF source power moves to one point present on the upper surface of the lower electrode 131 along the lower metal rod 132 and the surface of the lower electrode 131 from the output terminal of the lower V/I sensor 310a.

It is to be appreciated that the above description is an example for the upper RF path Pᵤ and the lower RF path Pₗ, and the upper RF path Pᵤ and the lower RF path Pₗ are not limited as such, and may be implemented in various forms.

FIG. 5 is a conceptual view illustrating a controlling method of an upper/lower RF generator by using a controller, consistent with some embodiments of the present disclosure.

Referring to FIG. 5, the controller 400 may be configured to obtain a waveform of an upper fundamental voltage Vᵤ₁ and waveforms of a plurality of upper harmonic voltages from the upper V/I sensor 210 and obtain a waveform of a lower fundamental voltage Vₗ₁ and waveforms of a plurality of lower harmonic voltages from the lower V/I sensor 310. However, in describing FIG. 5, for convenience of explanation, the description is based on the case where the waveforms of the plurality of upper harmonic voltages include only the waveform of a first upper harmonic voltage Vᵤ₂ and the waveform of a second upper harmonic voltage Vᵤ₃, and the waveforms of the plurality of lower harmonic voltages include only the waveform of a first lower harmonic voltage Vₗ₂ and the waveforms of a second lower harmonic voltage Vₗ₃.

In some embodiments, if the frequency of the upper fundamental voltage Vᵤ₁ is 60 MHz, the frequency of the first upper harmonic voltage Vᵤ₂ may be 120 MHz, and the frequency of the second upper harmonic voltage Vᵤ₃ may be 180 MHz. The frequency of the lower fundamental voltage Vₗ₁ may be 60 MHz, the frequency of the first lower harmonic voltage Vₗ₂, and the frequency of the second lower harmonic voltage Vₗ₃ may be 180 MHz.

In some embodiments, the controller 400 may identify an upper/lower fundamental phase difference φ_{d} based on the waveform of the upper fundamental voltage Vᵤ₁ and the waveform of the lower fundamental voltage Vₗ₁. The upper/lower fundamental phase difference φ_{d} refers to a phase difference between the upper fundamental voltage Vᵤ₁ and the lower fundamental voltage Vₗ₁.

Subsequently, the controller 400 may identify a first upper phase difference φ_{u1,2} and a second upper phase difference φ_{u1,3} based on the waveform of the upper fundamental voltage Vᵤ₁, on the waveform of the first upper harmonic voltage Vᵤ₂, and on the waveform of the second upper harmonic voltage Vᵤ₃. As used herein, the first upper phase difference φ_{u1,2} refers to a phase difference between the upper fundamental voltage Vᵤ₁ and the first upper harmonic voltage Vᵤ₂, and the second upper phase difference φ_{u1,3} refers to a phase difference between the upper fundamental voltage Vᵤ₁ and the second upper harmonic voltage Vᵤ₃. Based on the same principle, the controller 400 may identify the first lower phase difference φ_{l1,2} and the second lower phase difference φ_{l1,3} based on the waveform of the lower fundamental voltage Vₗ₁, the waveform of the first lower harmonic voltage Vₗ₂, and the waveform of the second lower harmonic voltage Vₗ₃.

Here, the upper/lower fundamental phase difference φ_{d} may be a constant, and the first upper phase difference φ_{u1,2} and the second upper phase difference φ_{u1,3}, the first lower phase difference φ_{l1,2}, and the second lower phase difference φ_{l1,3} may be values that change according to a constant time period.

The controller 400 may identify a fundamental upper phase compensation value (Δφ_{1,1}), a first upper phase compensation value (Δφ_{2,1}), a second upper phase compensation value Δφ_{3,1}) due to the upper RF path Pᵤ for each of the upper fundamental voltage Vᵤ₁, the first upper harmonic voltage Vᵤ₂, and the second upper harmonic voltage Vᵤ₃. In addition, the controller 400 may identify the fundamental lower phase compensation value (Δφ_{1,2}), the first lower phase compensation value (Δφ_{2,2}), and the second lower phase compensation value Δφ_{3,2}) due to the lower RF path Pₗ based on the same principle.

In some embodiments, the controller 400 may identify the above-described phase compensation values based on relative permittivity ε_{r,1} and a length l₁ of the upper RF path Pᵤ and relative permittivity ε_{r,2} and a length l₂ of the lower RF path Pₗ. The controller 400 may identify the fundamental upper phase compensation value (Δφ_{1,1}), the first upper phase compensation value (Δφ_{2,1}), the second upper phase compensation value (Δφ_{3,1}), the fundamental lower phase compensation value (Δφ_{1,2}), the first lower phase compensation value (Δφ_{2,2}), and the second lower phase compensation value (Δφ_{3,2}) based on Equation 1.

$$Δ {ϕ}_{x , y} = 2 π ( \frac{{l}_{y}}{{λ}_{x , y}} ) , {λ}_{x , y} = \frac{c}{{f}_{x} \sqrt{{ε}_{r , y}}} ( x = 1 , 2 , 3 , y = 1 , 2 ) \qquad [ Equation 1 ]$$

Here, a value of x indicates whether it is a fundamental voltage component (x=1), a first harmonic component (x=2), or a second harmonic component (x=3), and a value of y indicates whether it is upper (y=1) or lower (y=2), λ is the wavelength of each voltage component, f is a frequency of each voltage component, and l is a length of an RF path. For example, λ_{1,1} refers to a wavelength of the upper fundamental voltage Vᵤ₁, and f₁ and f₂ is a frequency of the first upper harmonic voltage Vᵤ₂ and a frequency of the first lower harmonic voltage Vₗ₂. In addition, each of l₁ and l₂ is the length of the upper RF path Pᵤ and the length of the lower RF path Pₗ.

The controller 400 may estimate the waveform of the upper RF voltage Vᵤ and the waveform of the lower RF voltage Vₗ based on the above-described phase compensation values, the waveform of the upper/lower fundamental voltage, and the waveform of the second upper/lower harmonic voltage. The controller 400 may estimate the waveform of the upper RF voltage Vᵤ based on Equation 2 and may estimate the waveform of the lower RF voltage Vₗ based on Equation 3.

$${V}_{u} = \vert {V}_{u 1} \vert sin ( 2 π {f}_{1} t + {ϕ}_{d} + Δ {ϕ}_{1 , 1} ) cos ( \frac{2 π r}{{λ}_{1 , 1}} ) / cos ( \frac{2 π {l}_{1}}{{λ}_{1 , 1}} ) + \vert {V}_{u 2} \vert sin ( 2 π {f}_{2} t + {ϕ}_{d} + {ϕ}_{u 1 , 2} + Δ {ϕ}_{2 , 1} ) cos ( \frac{2 π r}{{λ}_{2 , 1}} ) / cos ( \frac{2 π {l}_{1}}{{λ}_{2 , 1}} ) + \vert {V}_{u 3} \vert sin ( 2 π {f}_{3} t + {ϕ}_{d} + {ϕ}_{u 1 , 3} + Δ {ϕ}_{3 , 1} ) cos ( \frac{2 π r}{{λ}_{3 , 1}} ) / cos ( \frac{2 π {l}_{1}}{{λ}_{3 , 1}} ) \qquad [ Equation 2 ]$$

$${V}_{l} = \vert {V}_{l 1} \vert sin ( 2 π {f}_{1} t + Δ {ϕ}_{1 , 2} ) cos ( \frac{2 π r}{{λ}_{1 , 2}} ) / cos ( \frac{2 π {l}_{2}}{{λ}_{1 , 2}} ) + \vert {V}_{l 2} \vert sin ( 2 π {f}_{2} t + {ϕ}_{l 1 , 2} + Δ {ϕ}_{2 , 2} ) cos ( \frac{2 π r}{{λ}_{2 , 2}} ) / cos ( \frac{2 π {l}_{2}}{{λ}_{2 , 2}} ) + \vert {V}_{l 3} \vert sin ( 2 π {f}_{3} t + {ϕ}_{l 1 , 3} + Δ {ϕ}_{3 , 2} ) cos ( \frac{2 π r}{{λ}_{3 , 2}} ) / cos ( \frac{2 π {l}_{2}}{{λ}_{3 , 2}} ) \qquad [ Equation 3 ]$$

In Equation 2, |Vᵤ₁|, |Vᵤ₂|, |Vᵤ₃| refer to the amplitude of the upper fundamental voltage Vᵤ₁, the amplitude of the first upper harmonic voltage Vᵤ₂, and the amplitude of the second upper harmonic voltage Vᵤ₃, respectively. In addition, r may mean a radius distance between the center of the upper electrode 121 to one point present on the lower surface of the upper electrode 121.

In Equation 3, |Vᵤ₁, |Vₗ₂|, |Vₗ₃| refer to the amplitude of the lower fundamental voltage Vₗ₁, the amplitude of the first lower harmonic voltage Vₗ₂, and the amplitude of the second lower harmonic voltage Vₗ₃, respectively. In addition, r may mean a radius distance from the center of the lower electrode 131 to one point present on the upper surface of the lower electrode 131.

The controller 400 may estimate a voltage value applied to an arbitrary point (e.g., a point where r=3 mm) present on the lower surface of the upper electrode 121 at an arbitrary time point (e.g., a time point where t=2 seconds) based on Equation 2. Based on the same principle, the controller 400 may estimate a voltage value applied to an arbitrary point present on the upper surface of the lower electrode 131 at an arbitrary time point based on Equation 3. The waveform of the upper RF voltage Vᵤ and the waveform of the lower RF voltage Vₗ estimated by the controller 400 may be implemented in the form of a standing wave.

Subsequently, the controller 400 may compare the estimated waveform of the upper RF voltage Vᵤ with the waveform of a target upper voltage V_{u,target} and compare the estimated waveform of the lower RF voltage Vₗ with the waveform of a target lower voltage V_{l,target}. When there is a difference between the waveform of the upper RF voltage Vᵤ and the waveform of the target upper voltage V_{u,target}, the controller 400 may control the upper RF generator 230 to change the phase of the upper RF source power by the upper phase modulation value Ø_{c1}. Based on the same principle, the controller 400 may control the lower RF generator 330 to change the phase of the lower RF source power by the lower phase modulation value Ø_{c2}.

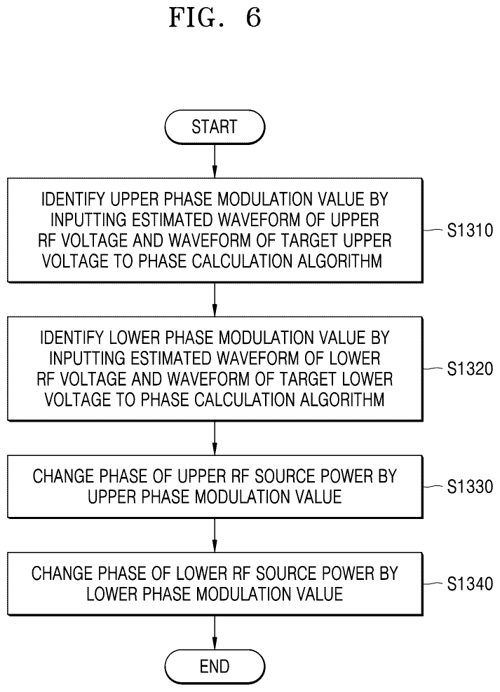

A method of identifying the upper phase modulation value Ø_{c1} and the lower phase modulation value Ø_{c2} and controlling the upper RF generator 230 and the lower RF generator 330 by using the controller 400 is described with reference to FIG. 6.

FIG. 6 is a flowchart illustrating a controlling method of the plasma control apparatus 10, consistent with some embodiments of the present disclosure. This will be described with reference to FIG. 1 (or FIG. 4).

Referring to FIG. 6, in the controlling method of the plasma control apparatus 10, an operation of identifying the upper phase modulation value Ø_{c1} by inputting the estimated waveform of the upper RF voltage Vᵤ and the waveform of the target upper voltage V_{u,target} to a phase calculation algorithm (S1310) may be performed.

In operation S1320, an operation of identifying the lower phase modulation value Ø_{c2} by inputting the estimated waveform of the lower RF voltage Vₗ and the waveform of the target lower voltage V_{l,target} to the phase calculation algorithm (S1320) may be performed.

Although FIG. 6 illustrates that the operation of identifying the upper phase modulation value Ø_{c1} (S1310) is performed and the operation of identifying the lower phase modulation value Ø_{c2} (S1320) is performed, the operation of identifying the upper phase modulation value Ø_{c1} and the operation of identifying the lower phase modulation value Ø_{c2} (S1320) may be simultaneously performed, and the operation of identifying the lower phase modulation value Ø_{c2} (S1320) may also be performed before the operation of identifying the upper phase modulation value Ø_{c1} (S1310).

The above-described phase calculation algorithm may mean an algorithm for searching a “phase modulation value” in which a changed upper/lower voltage Vᵤ′/Vₗ′ is calculated by applying an arbitrary “phase modulation value” to the upper/lower RF voltage Vᵤ/Vₗ and an error between the changed upper/lower voltage Vᵤ′/Vₗ′ and the target upper/lower voltage V_{u,target}/V_{l,target} may be minimized.

Here, a method of calculating the changed upper/lower voltage Vᵤ′/Vₗ′ by using the controller 400 may be performed by substituting an arbitrary phase modulation value into a phase term of three sine functions included in each of Equations 2 and 3. For example, the controller 400 may calculate the changed upper voltage Vᵤ′ by substituting a phase modulation value “+10 degrees” into the phase term of three sine functions included in Equation 2.

According to an embodiment, the phase calculation algorithm may be expressed in Equations 4 and 5. However, Equations 4 and 5 are just one example, and the phase calculation algorithm may also be implemented with various types of algorithms.

$${∅}_{c 1} = arg {min}_{∅} {\{ {V}_{u , target} - {V}_{u}^{′} \}}^{2} \qquad [ Equation 4 ]$$

$${∅}_{c 2} = arg {min}_{∅} {\{ {V}_{l , target} - {V}_{l}^{′} \}}^{2} \qquad [ Equation 5 ]$$

In some embodiments, the phase calculation algorithm may also be implemented with a greedy algorithm. In some embodiments, the phase calculation algorithm may also be implemented with a matrix calculation algorithm based on a Pseudo Inverse method. The controller 400 may identify the upper phase modulation value Ø_{c1} and the lower phase modulation value Ø_{c2} using the above-described phase calculation algorithm.

In operation S1330, the operation of changing the phase of the upper RF source power by the upper phase modulation value Ø_{c1} (S1330) may be performed. In addition, the operation of changing the phase of the lower RF source power by the lower phase modulation value Ø_{c2} (S1340) may be performed.

Although FIG. 6 illustrates that the operation of changing the phase of the upper RF source power (S1330) is performed and the operation of changing the phase of the lower RF source power (S1340) is performed, the operation of changing the phase of the upper RF source power (S1330) and the operation of changing the phase of the lower RF source power (S1340) may be simultaneously performed, and the operation of changing the phase of the lower RF source power (S1340) may also be performed before the operation of changing the phase of the upper RF source power (S1330).

In some embodiments, the controller 400 may control the upper RF generator 230 to change the phase of the upper RF source power by the upper phase modulation value Ø_{c1}. In addition, the controller 400 may control the lower RF generator 330 to change the phase of the lower RF source power by the lower phase modulation value Ø_{c2}.

Although not shown in FIG. 6, the controller 400 may also control the upper harmonic generator 240 and the lower harmonic generator 340.

Even after the phase of the upper RF source power is changed by the upper phase modulation value Ø_{c1} and the phase of the lower RF source power is changed by the lower phase modulation value Ø_{c2}, due to the effect of the plurality of upper harmonic voltages and the plurality of lower harmonic voltages, the waveform of the upper/lower RF voltage may not be identical or substantially similar to the waveform of the target upper/lower voltage. In this case, the controller 400 may control the upper harmonic generator 240 and/or the lower harmonic generator 340 to suppress the effect of the plurality of upper harmonic voltages and the plurality of lower harmonic voltages.

In some embodiments, the controller 400 may control the upper harmonic generator 240 to change the phases of the plurality of upper harmonic voltages applied to the upper electrode 121, and may control the lower harmonic generator 340 to change the phases of the plurality of lower harmonic voltages applied to the lower electrode 131.

In some embodiments, the controller 400 may control the upper harmonic generator 240 to change amplitudes of the plurality of upper harmonic voltages applied to the upper electrode 121, and may control the lower harmonic generator 340 to change amplitudes of the plurality of lower harmonic voltages applied to the lower electrode 131.

In some embodiments, the upper harmonic generator 240 and/or the lower harmonic generator 340 are controlled after the phase of the upper RF source power is changed by the upper phase modulation value Ø_{c1} and the phase of the lower RF source power is changed by the lower phase modulation value Ø_{c2}. However, in some embodiments, the upper harmonic generator 240 and/or the lower harmonic generator 340 may be controlled simultaneously with controlling the phase of the upper RF source power and the phase of the lower RF source power.

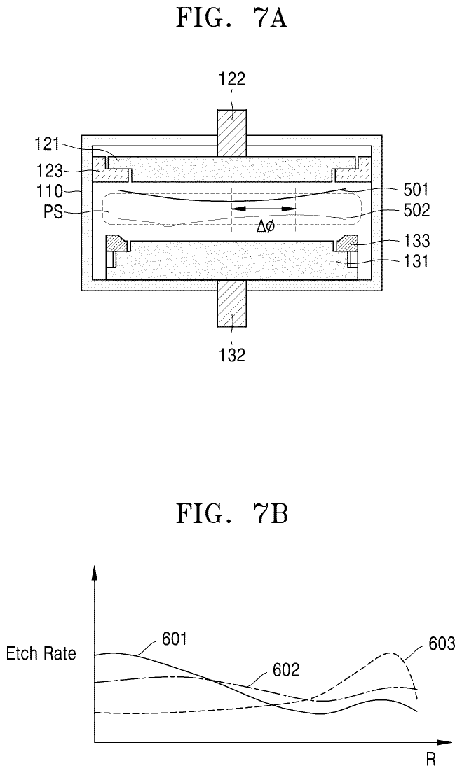

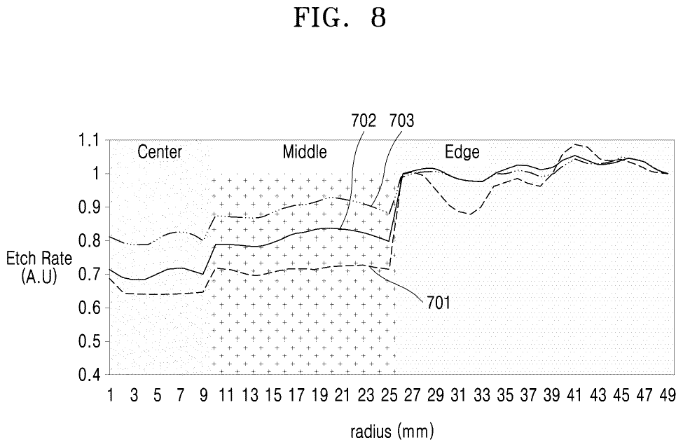

As previously described, the controller 400 may control each of the upper RF generator 230, the upper harmonic generator 240, the lower RF generator 330, and the lower harmonic generator 340 to change the waveforms of the upper/lower RF voltages applied to the upper electrode 121 and the lower electrode 131 to be identical/similar to the waveforms of the target upper/lower voltage. Thus, the distribution of plasma formed inside the plasma chamber 100 may be changed. FIGS. 7A, 7B and 8 describe the distribution of plasma changed according to the phase control of the plasma control apparatus 10.

FIGS. 7A and 7B show a cross-sectional view and a graph, respectively, illustrating a controlling method of a plasma control apparatus, consistent with some embodiments of the present disclosure.

Referring to FIG. 7A, a phase difference between the upper RF voltage 501 applied to the upper electrode 121 and the lower RF voltage 502 applied to the lower electrode 131 may be an upper/lower phase difference Aq.

FIG. 7B is a graph showing an etch rate of the wafer arranged on the upper surface of the lower electrode 131 according to a radius distance R of the water. A first curve 601 included in the graph illustrated in FIG. 7B represents the etch rate of the wafer when the upper/lower phase difference is the first phase difference (Δφ=(1), and a second curve 602 and a third curve 603 are curves representing the etching rate of the wafer when the upper/lower phase difference is the second phase difference (Δφ=42) and the etch rate of the wafer when the upper/lower phase difference is the third phase difference (Δφ=(3), respectively. Here, the first phase difference φ1, the second phase difference φ2, and the third phase difference φ3 may be different from another. For example, the first phase difference φ1 may be 30 degrees, the second phase difference φ2 may be 60 degrees, and the third phase difference φ3 may be −30 degrees.

Referring to each curve in FIG. 7B, the second curve 602 shows the most uniform etch rate distribution. In other words, the distribution of plasma formed within a plasma formation space PS may be most uniform when the upper/lower phase difference is the second phase difference (Δφ=φ2).

As shown in FIGS. 7A and 7B, the plasma control apparatus 10 may change the distribution of plasma by changing the phase of the upper RF voltage and the phase of the lower RF voltage, respectively, and thus uniform etch rate distribution can be obtained.

FIG. 8 is a graph illustrating a controlling method of a plasma control apparatus, consistent with some embodiments of the present disclosure.

FIG. 8 shows curves representing the etch rate distribution according to the phase control of the plasma control apparatus 10 in the environment of the plasma chamber 100 where an edge-hot phenomenon may occur.

Referring to FIG. 8, a first etch rate curve 701 is a curve showing etch rate distribution according to the radius of the wafer when the phase of the upper RF source power is changed by +120 degrees. A second etch rate curve 702 and a third etch rate curve 703 are curves showing the etch rate distribution according to the radial distance of the wafer when the phase of the upper RF source power is changed by −140 degrees and −60 degrees, respectively.

“Center”, “Middle”, and “Edge” may represent the center region of the wafer, the middle region of the wafer, and the edge region of the wafer, respectively. Here, the middle region of the wafer may mean a region between the center region and the edge region.

Referring to FIG. 8, the first etch rate curve 701, the second etch rate curve 702, and the third etch rate curve 703 all show relatively high etch rates in the edge region. Additionally, the third etch rate curve 703 shows relatively high etch rate distribution in the central region and middle region compared to the first etch rate curve 701 and the second etch rate curve 702. In other words, the third etch rate curve 703 shows relatively high etch rate distribution in the central region and middle region compared to the first etch rate curve 701 and the second etch rate curve 702.

As illustrated in FIG. 8, the phase of the upper RF source power is changed in the environment of the plasma chamber 100 where the edge-hot phenomenon may occur, the plasma density in the central region and the middle region may be increased, and thus, uniform etch rate distribution may be obtained.

With reference to FIG. 8, although only the environment of the plasma chamber 100 where the edge-hot phenomenon occurs has been described as an example, it is not limited as such. For example, in some embodiments, the phase control method may be applied even in various operating environments including where a center-hot phenomenon occurs, the plasma density in the middle region and the edge region may be increased based on the phase control of the plasma control apparatus 10.

Also, with reference to FIG. 8, although only that the phase of the upper RF source power is changed, it is not limited as such. In some embodiments, the plasma control apparatus 10 may obtain an etch rate curve similar to the graph illustrated in FIG. 8 by changing the phase of the upper RF source power and/or the phase of the lower RF source power.

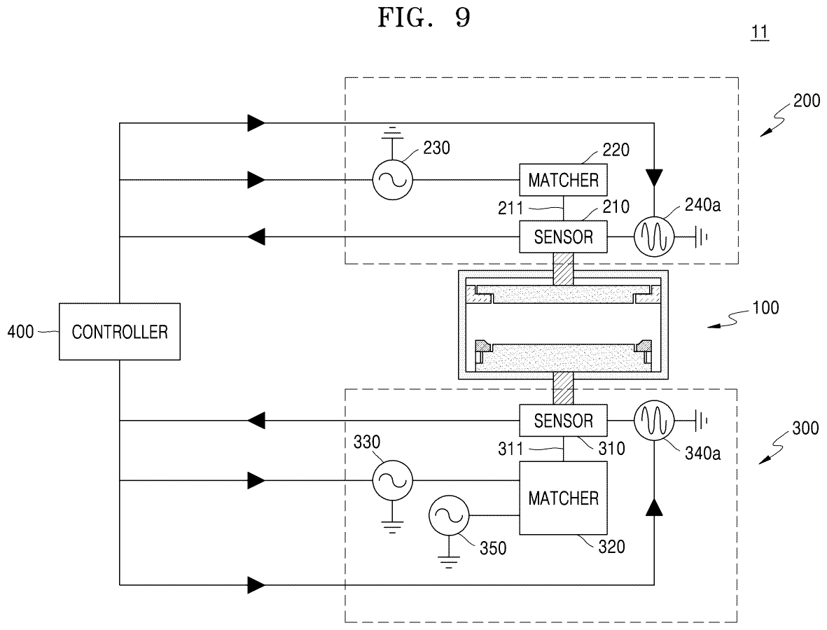

FIG. 9 is a configuration view schematically illustrating a plasma control apparatus 11, consistent with some embodiments of the present disclosure.

The plasma control apparatus 11 may include substantially the same configurations as the plasma control apparatus 10 illustrated in FIG. 1, and thus, in the description of FIG. 9, redundant contents with the description of FIG. 1 will be omitted.

Referring to FIG. 9, the plasma control apparatus 11 may further include an upper harmonic generator 240a and a lower harmonic generator 340a.

In some embodiments, the upper harmonic generator 240a may be electrically connected to the upper electrode 121 and may not be connected to the upper matcher 220. In addition, the lower harmonic generator 340a may be electrically connected to the lower electrode 131 and may not be connected to the lower matcher 320. That is, since impedance matching does not need to be performed for the upper harmonic generator 240a and the lower harmonic generator 340a, the upper harmonic generator 240a and the lower harmonic generator 340a may not be connected to the upper matcher 220 and the lower matcher 320. In addition, each of the upper harmonic generator 240a and the lower harmonic generator 340a may be connected to the upper V/I sensor 210 and the lower V/I sensor 310.

FIG. 10 is a configuration view schematically illustrating a plasma control apparatus, consistent with some embodiments of the present disclosure.

A plasma control apparatus 12 illustrated in FIG. 10 includes substantially the same configurations as the plasma control apparatus 10 illustrated in FIG. 1 and the plasma control apparatus 11 illustrated in FIG. 9. Thus, in the description of FIG. 10, redundant contents with the descriptions of FIG. 1 and FIG. 9 will be omitted.

Referring to FIG. 10, the plasma control apparatus 12 may further include the upper V/I sensor 210a and the lower V/I sensor 310a.

In some embodiments, the upper V/I sensor 210a and the lower V/I sensor 310a may be arranged inside the housing 110. Specifically, the upper V/I sensor 210a may be arranged between the upper surface of the housing 110 and the upper electrode 121, and the lower V/I sensor 310a may be arranged between the lower surface of the housing 110 and the lower electrode 131.

As previously described, each of the upper V/I sensor 210a and the lower V/I sensor 310a may be arranged adjacent to the upper electrode 121 and the lower electrode 131. Accordingly, the upper V/I sensor 210a may be arranged coupled to the upper metal rod 122 and may be arranged in contact with or very adjacent to the upper surface of the upper electrode 121. Accordingly, the lower V/I sensor 310a may be arranged coupled to the lower metal rod 132 and may be arranged in contact with or very adjacent to the lower surface of the lower electrode 131.

In some embodiments, a distance between the upper V/I sensor 210a and the upper electrode 121 may be smaller than a distance between the upper V/I sensor 210a and the upper surface of the housing 110, and a distance between the lower V/I sensor 310a and the lower electrode 131 may be smaller than a distance between the lower V/I sensor 310a and the lower surface of the housing 110.

Although exemplary embodiments have been described, the present disclosure should not be limited to these embodiments, but various changes and modifications can be made by one ordinary skilled in the art within the spirit and scope of the present disclosure as hereinafter claimed.

What is claimed is:

1. A plasma control apparatus, comprising:
a first radio frequency (RF) circuit connected to an upper electrode of a plasma chamber, a first RF generator associated with the first RF circuit, the first RF generator configured to supply a first RF source power signal to the upper electrode;
a second RF circuit connected to a lower electrode of the plasma chamber, a second RF generator associated with the second RF circuit, the second RF generator configured to supply a second RF source power signal to the lower electrode;
a first voltage sensor configured to obtain a first voltage signal information associated with the first RF circuit;
a second voltage sensor configured to obtain a second voltage signal information associated with the second RF circuit; and
a controller communicatively coupled with the first and the second RF circuits, the controller configured to:
determine a first waveform of a first RF voltage signal component at the upper electrode based on the first voltage signal information;
determine a second waveform of a second RF voltage signal component at the lower electrode based on the second voltage signal information;
adjust a first phase of the first RF source power signal such that a first error between the first waveform of the first RF voltage signal component and a first target waveform of the first RF voltage signal component is minimized; and
adjust a second phase of the second RF source power signal such that a second error between the second waveform of the second RF voltage signal component and a second target waveform of the second RF voltage signal component is minimized.

2. The plasma control apparatus of claim 1, wherein the first voltage signal information comprises voltage information associated with at least one of a waveform of a first fundamental voltage signal and waveforms of a first plurality of harmonic voltage signals.

3. The plasma control apparatus of claim 2, wherein the second voltage signal information comprises voltage information associated with at least one of a waveform of a second fundamental voltage signal and waveforms of a second plurality of harmonic voltage signals.

4. The plasma control apparatus of claim 3, wherein the controller is further configured to determine the first waveform of the first RF voltage signal component by correcting at least one of the waveform of the first fundamental voltage signal and the waveforms of the first plurality of harmonic voltage signals based on a first length of a first RF transmission line along which the first RF source power signal is transmitted from the first voltage sensor to the upper electrode.

5. The plasma control apparatus of claim 4, wherein the controller is further configured to determine the second waveform of the second RF voltage signal component by correcting at least one of the waveform of the second fundamental voltage signal and the waveforms of the second plurality of harmonic voltage signals based on a second length of a second RF transmission line along which the second RF source power signal is transmitted from the second voltage sensor to the lower electrode.

6. The plasma control apparatus of claim 5, wherein the controller is further configured to:
determine, using a phase calculation algorithm, a first phase modulation value based on the determined waveform of the first RF voltage signal component and the first target waveform of the first RF voltage signal component, and
determine, using the phase calculation algorithm, a second phase modulation value based on the determined waveform of the second RF voltage signal component and the second target waveform of the first RF voltage signal component.

7. The plasma control apparatus of claim 6, wherein the controller is further configured to:
control the first RF generator to adjust the first phase of the first RF source power signal based on the determined first phase modulation value; and
control the second RF generator to adjust the second phase of the second RF source power signal based on the determined second phase modulation value.

8. The plasma control apparatus of claim 7, wherein a frequency of each of the first plurality of harmonic voltage signals is an integer multiple of a frequency of the first fundamental voltage signal, wherein the integer multiple is at least 2.

9. The plasma control apparatus of claim 8, wherein a frequency of each of the second plurality of harmonic voltage signals is an integer multiple of a frequency of the second fundamental voltage signal, wherein the integer multiple is at least 2.

10. The plasma control apparatus of claim 9, wherein the first RF circuit comprises a first harmonic generator configured to generate a harmonic voltage signal having a same frequency as at least one of the first plurality of harmonic voltage signals.

11. The plasma control apparatus of claim 10, wherein the second RF circuit comprises a second harmonic generator configured to generate a harmonic voltage signal having a same frequency as at least one of the second plurality of harmonic voltage signals.

12. The plasma control apparatus of claim 11, wherein the controller is further configured to control the first harmonic generator to change a phase of each of the first plurality of harmonic voltage signals applied to the upper electrode and to change an amplitude of each of the first plurality of harmonic voltage signals applied to the upper electrode.

13. The plasma control apparatus of claim 12, wherein the controller is further configured to control the second harmonic generator to change a phase of each of the second plurality of harmonic voltage signals applied to the lower electrode and to change an amplitude of each of the second plurality of harmonic voltage signals applied to the lower electrode.

14. The plasma control apparatus of claim 13, wherein the first RF circuit further comprises a first matching circuit connected to the first RF generator, the first matching circuit being configured to adjust an impedance of the first RF source power signal supplied to the upper electrode.

15. The plasma control apparatus of claim 14, wherein the second RF circuit further comprises a second matching circuit connected to the second RF generator, the second matching circuit being configured to adjust an impedance of the second RF source power signal supplied to the lower electrode.

16. The plasma control apparatus of claim 15, wherein the first voltage sensor is coupled to the first RF transmission line connecting the first matching circuit to the upper electrode.

17. The plasma control apparatus of claim 16, wherein the second voltage sensor is coupled to the second RF transmission line connecting the second matching circuit to the lower electrode.

18. A plasma control apparatus, comprising:
a housing connected to a ground potential, the housing comprising a plasma formation space;
an upper electrode arranged in an upper portion of the plasma formation space;
a lower electrode arranged in a lower portion of the plasma formation space, the lower electrode comprising an upper surface configured to receive a substrate;
a first RF circuit connected to the upper electrode, the first RF circuit comprising:
a first radio frequency (RF) generator configured to supply a first RF source power signal to the upper electrode;
a first matching circuit connected to the first RF generator and configured to adjust an impedance of the first RF source power signal; and
a first voltage sensor connected to the first matching circuit and the upper electrode and configured to obtain a first voltage signal information;
a second RF circuit connected to the lower electrode, the second RF circuit comprising:
a second radio frequency (RF) generator configured to supply a second RF source power signal to the lower electrode;
a second matching circuit connected to the second RF generator and configured to adjust an impedance of the second RF source power signal; and
a second voltage sensor connected to the second matching circuit and the lower electrode and configured to obtain a second voltage signal information,
wherein the upper electrode and the lower electrode are configured to generate a plasma for treating the substrate; and
a controller communicatively coupled with the first and the second RF circuits, the controller configured to:
determine a first waveform of a first RF voltage signal component at the upper electrode based on the first voltage signal information;
determine a second waveform of a second RF voltage signal component at the lower electrode based on the second voltage signal information;
adjust a first phase of the first RF source power signal such that a first error between the first waveform of the first RF voltage signal component and a first target waveform of the first RF voltage signal component is minimized; and
adjust a second phase of the second RF source power signal such that a second error between the second waveform of the second RF voltage signal component and a second target waveform of the second RF voltage signal component is minimized.

19. The plasma control apparatus of claim 18, wherein the first voltage signal information comprises voltage information associated with at least one of a waveform of a first fundamental voltage signal and waveforms of a first plurality of harmonic voltage signals, and wherein the second voltage signal information comprises voltage information associated with at least one of a waveform of a second fundamental voltage signal and waveforms of a second plurality of harmonic voltage signals.

20. A plasma control apparatus, comprising:
an upper electrode arranged in an upper portion of a plasma formation space;
a lower electrode arranged in a lower portion of the plasma formation space;
a first radio frequency (RF) generator configured to supply a first RF source power signal to the upper electrode;
a first voltage sensor connected to the upper electrode and configured to obtain a first voltage signal information;
a second radio frequency (RF) generator configured to supply a second RF source power signal to the lower electrode;
a second voltage sensor connected to the lower electrode and configured to obtain a second voltage signal information;
a controller communicatively coupled with the first and the second RF generators, the controller configured to:
determine a first waveform of a first RF voltage signal component at the upper electrode based on the first voltage signal information;
determine a second waveform of a second RF voltage signal component at the lower electrode based on the second voltage signal information;
adjust a first phase of the first RF source power signal such that a first error between the first waveform of the first RF voltage signal component and a first target waveform of the first RF voltage signal component is minimized; and
adjust a second phase of the second RF source power signal such that a second error between the second waveform of the second RF voltage signal component and a second target waveform of the second RF voltage signal component is minimized.
